(19) United States
(12) Patent Application Publication
(10) Pub. No.: US 2018/0127143 A1
(43) Pub. Date: May 10, 2018

(54) METAL BASKET AND METHOD FOR MAKING THE SAME

(71) Applicant: Chuan-Ching YEH, Hemei Township (TW)

(72) Inventor: Chuan-Ching YEH, Hemei Township (TW)

(73) Assignees: Chuan-Ching Yeh, Hemei Township (TW); DONIDO ENTERPRISE CO., LTD., Huatan Township (TW)

(21) Appl. No.: 15/587,603

(22) Filed: May 5, 2017

(30) Foreign Application Priority Data
Nov. 10, 2016 (TW) 105136575

(51) Int. Cl. B65D 6/34; B21F 33/02; B65D 6/08; C23G 1/00; C23C 14/34; C25D 5/34; C25D 11/02; C25D 13/20

(52) U.S. Cl. CPC B65D 7/44; B21F 33/02; B65D 7/14; C25D 13/20; C23C 14/34; C25D 5/34; C25D 11/02; C23G 1/00

(57) ABSTRACT

A method for making a basket includes the following steps. An expanded mesh basket and a frame are previously prepared, wherein the frame has a hollow loop-shaped structure. The expanded mesh basket has a receiving space defined therein and an open end communicating with the receiving space. A flange extends from a periphery of the open end and the frame has an annular slit defined therein for receiving the flange. The expanded mesh basket and the frame are respectively processed to peripherally form a coating, wherein the coating of the expanded mesh basket is different that of the frame. The flange of the expanded mesh basket extends into the ring of slot and the frame is clamp by a mold to securely assembled the expanded mesh basket and frame.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

### 1. Field of the Invention

The present invention relates to a metal basket, and more particularly to a metal basket that has an expanded mesh bracket and a frame, wherein the expanded mesh basket and the frame are respectively processed and have different colors.

### 2. Description of Related Art Including Information Disclosed Under 37 CFR 1.97 and 37 CFR 1.98

A metal basket has an expanded mesh basket and a frame, and is usually used for storing objects. In addition, multiple baskets can be staggered for making full use of space or arranged on a tabletop for showing products. Consequently, the metal basket has been a popular storing tool to the consumers.

However, the conventional method for making a metal basket cannot be broken through and has the following disadvantages. The conventional method assembles the expanded mesh basket and the frame by rolling or stamping. However, the periphery of each of the expanded mesh basket and the frame is often scratched during assembling the basket and the frame. Consequently, the expanded mesh basket and the frame must be previously assembled before the step of surface treatment. As a result, the metal basket made by the conventional method always has a single-color and the additional value of the single-color metal basket cannot be raised by visual effects.

The present invention has arisen to mitigate and/or obviate the disadvantages of the conventional metal basket and the method for making the same.

### BRIEF SUMMARY OF THE INVENTION

The main objective of the present invention is to provide an improved method for making a metal basket that has an expanded mesh bracket and a frame, wherein the expanded mesh basket and the frame are respectively processed and have different colors.

To achieve the objective, the method in accordance with the present invention comprises the following steps. Preparing an expanded mesh basket and a hollow frame: the frame is hollow annular structure. The expanded mesh basket is formed with an open end and has a containing space defined therein, wherein the expanded mesh basket has a flange peripherally extending therefrom relative to the open end. The frame has an annular slit inwardly defined in the frame. Surface treatment: the expanded mesh basket and the frame are respectively processed by different surface treatment method and respectively peripherally formed with a protective coating, wherein the protective coating of the expanded mesh basket has a color different from that of the protective coating of the frame. Assembling the expanded mesh basket and the frame: the flange is inserted into the frame through the annular slit in the frame. Securing the expanded mesh basket with the frame: the frame is pressed and deformed by a mold such that the flange is securely clamped between two opposite sides of the annular slit.

Further benefits and advantages of the present invention will become apparent after a careful reading of the detailed description with appropriate reference to the accompanying drawings.

### BRIEF DESCRIPTION OF THE SEVERAL VIEWS OF THE DRAWINGS

FIG. 1 is a flow chart of a method for making metal basket in accordance with the present invention.

FIG. 2 is an exploded perspective view of a metal basket in accordance with the present invention.

FIGS. 3-5 are operational views for showing the assembling steps for assembling an expanded mesh basket and a frame.

FIG. 5A is a partially cross-sectional view of the metal basket in accordance with the present invention.

FIG. 6 is a perspective view of the metal basket in accordance with the present invention.

FIG. 7 is a partially perspective view of the metal basket in accordance with the present invention.

FIG. 8 is a cross-sectional view of a second embodiment of the frame in accordance with the present invention.

FIG. 9 is a cross-sectional view of a third embodiment of the frame in accordance with the present invention.

### DETAILED DESCRIPTION OF THE INVENTION

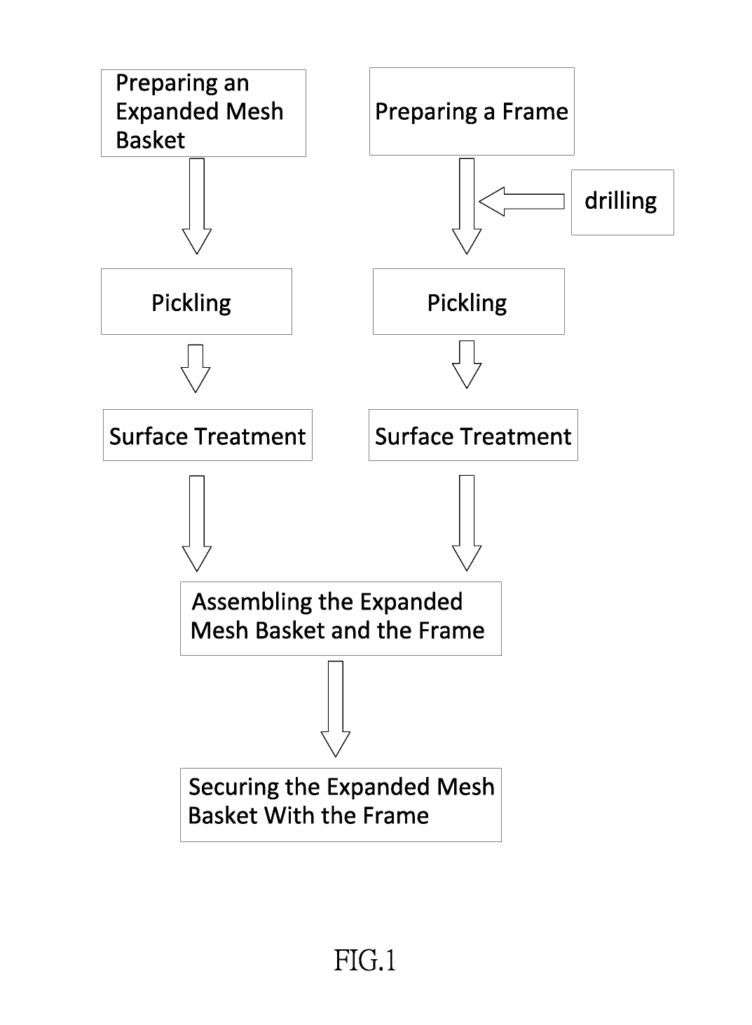

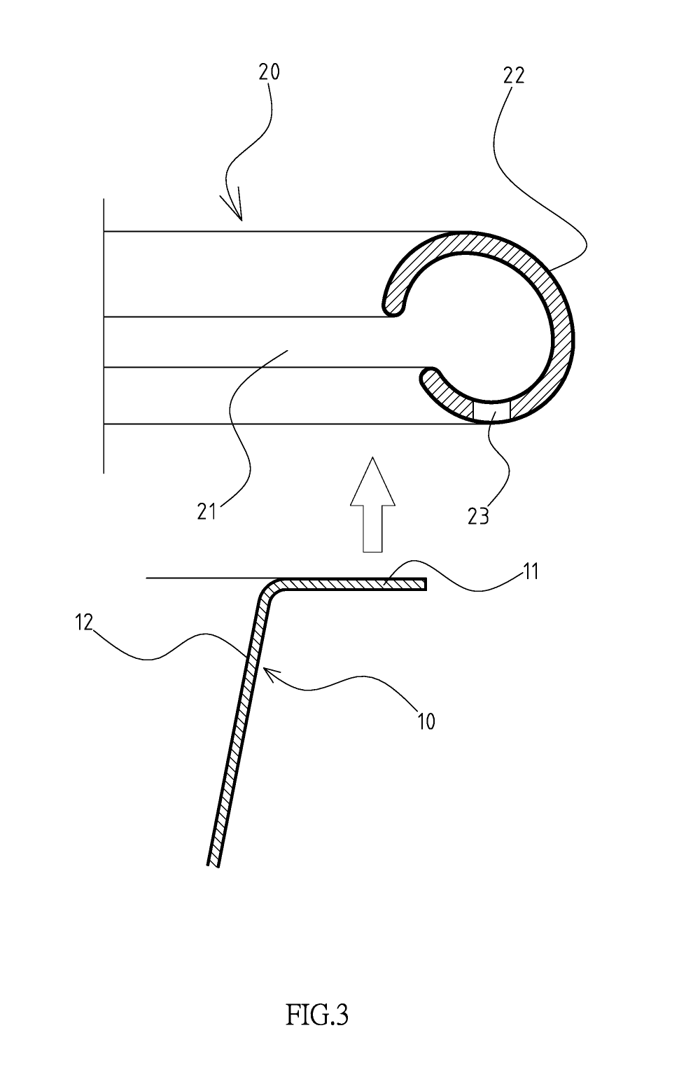

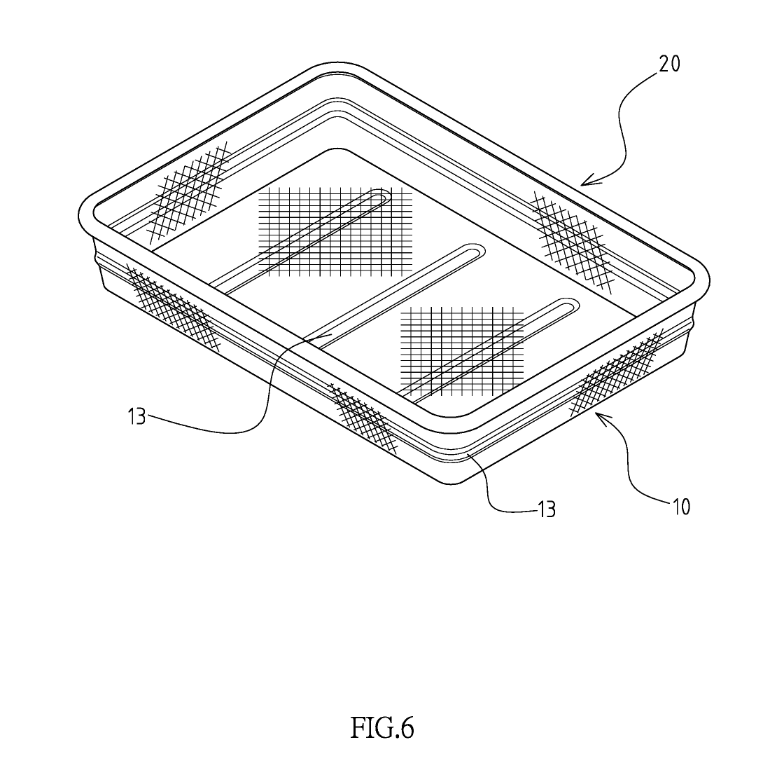

Referring to the drawings and initially to FIGS. 1-6, a method for making a metal basket in accordance with the present invention comprises the following steps.

Preparing an expanded mesh basket 10 and a hollow frame 20: the frame 20 is hollow annular structure. The expanded mesh basket 10 is formed with an open end and has a containing space (not numbered) defined therein, wherein the expanded mesh basket 10 has a flange 11 peripherally extending therefrom relative to the open end. In the preferred embodiment of the present invention, the flange 11 horizontally and outwardly extends from the expanded mesh basket 10.

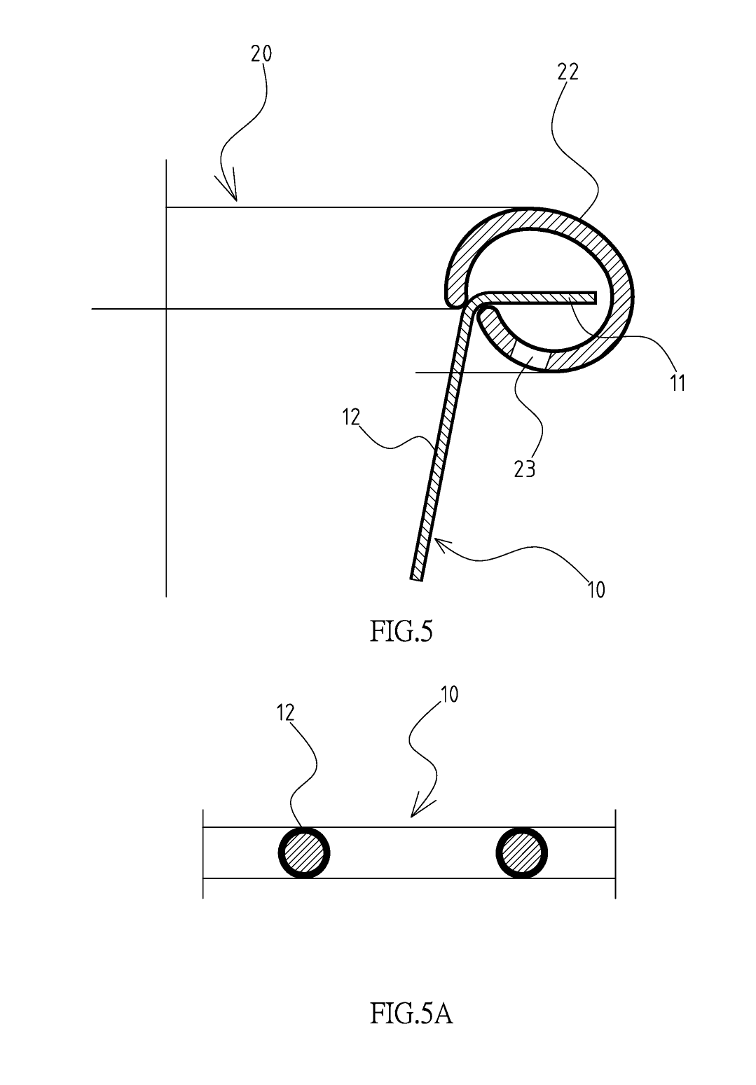

Surface treatment: with reference to FIG. 5A, the expanded mesh basket 10 and the frame 20 are respectively processed by different surface treatment method and respectively peripherally formed with a protective coating 12/22, wherein the protective coating 12 of the expanded mesh basket 10 has a color different from that of the protective coating 22 of the frame 20.

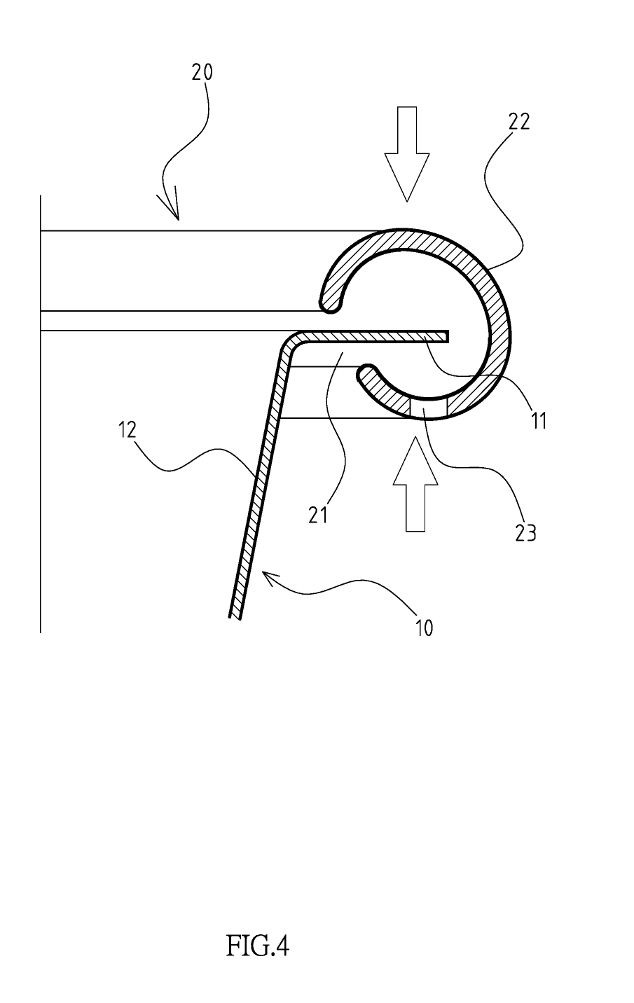

Assembling the expanded mesh basket 10 and the frame 20: with reference to FIG. 4, the frame 20 has an annular slit 21 inwardly defined therein and the flange 11 is inserted into the frame 20 through the annular slit 21.

Securing the expanded mesh basket 10 with the frame 20: the frame 20 is pressed and deformed by a mold (not shown) such that the flange 11 is securely clamped between two opposite sides of the annular slit 21, wherein the mold includes flexible structure disposed therein and corresponding to the frame 20 to prevent the protective coating 22 of the frame 20 from being scratched by the mold during being clamped.

In the preferred embodiment of the present invention, the surface treatment method of the expanded mesh basket 10 and the frame 20 is selected from the group consisted of baking finish, electroplating, anodic treatment, powder-paint coating, vapor deposition, sputtering and electrophoretic deposition.

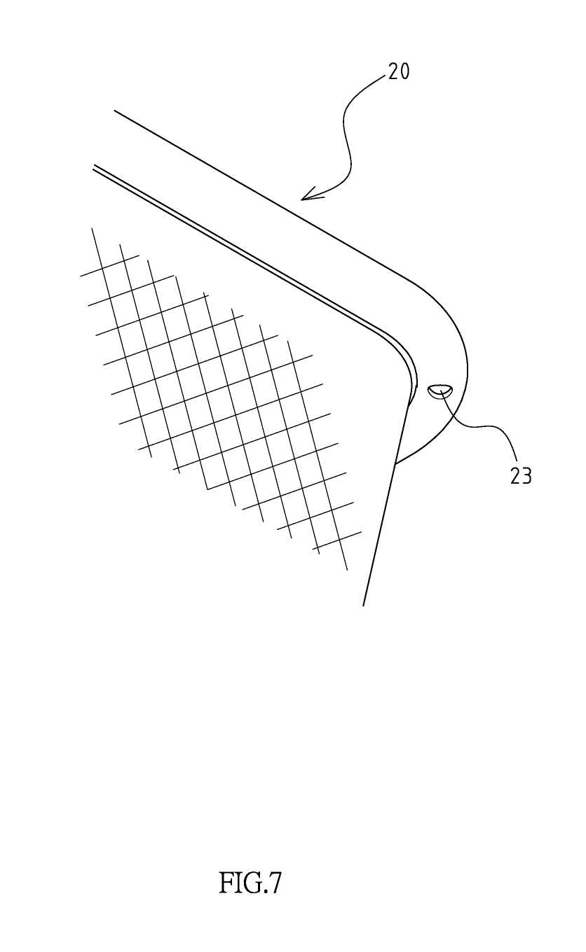

For improving the surface treatment effect and raising the peripheral brightness, the expanded mesh basket 10 and the frame 20 are pickled for removing the oxide and rust on the periphery of each of the expanded mesh basket 10 and the frame 20 before the step of surface treatment. With reference to FIG. 7, at least one through hole 23 is defined in the frame 20 for draining the pickle in the hollow frame 20 after being pickled.

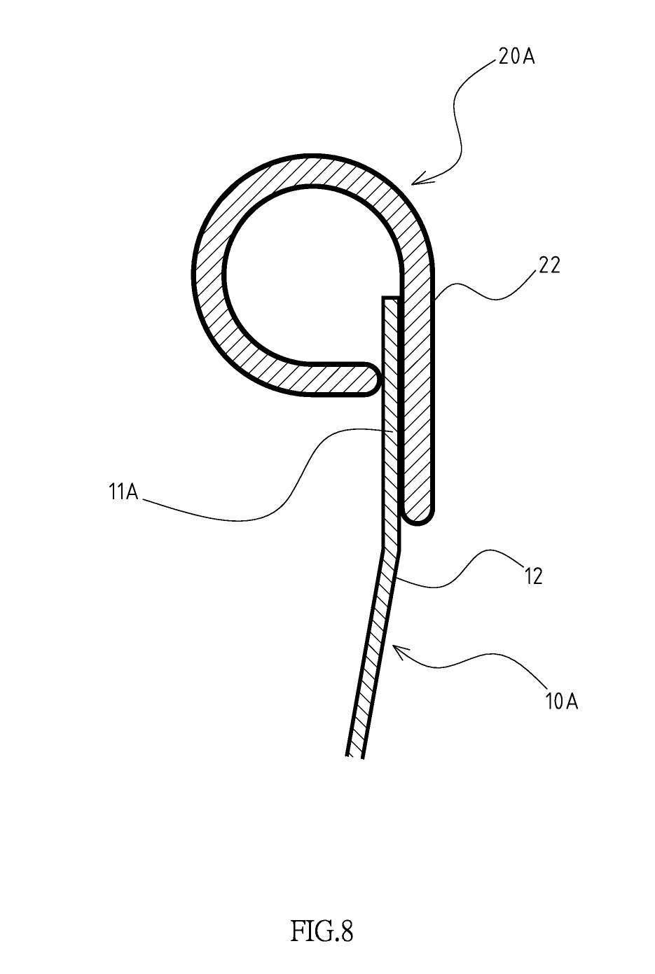

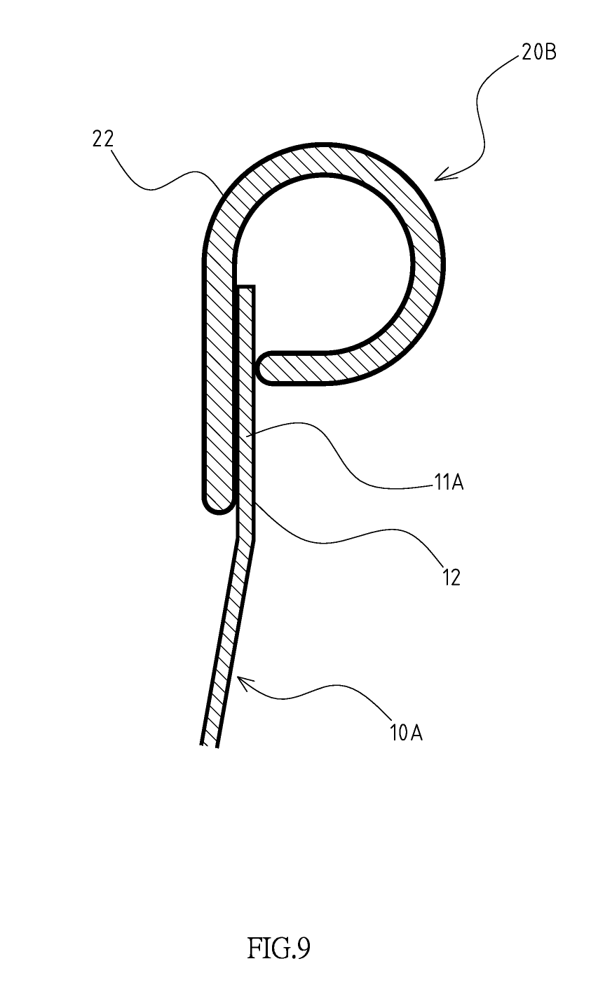

With reference to FIG. 8 that shows a second embodiment of the present invention, in this embodiment, the frame 20A has a 9-shaped cross-section and the flange 11A of the expanded mesh basket 10A is upwardly extended. With reference to FIG. 9 that shows a third embodiment of the present invention, in this embodiment, the frame 20B has a P-shaped cross-section and the flange 11A of the expanded mesh basket 10A is upwardly extended.

Generally speaking, the expanded mesh basket 10 is usually formed by marketed expanded mesh for reducing manufacturing cost. However, the marketed expanded mesh has a weak structure. Consequently, at least one of a bottom of the basket 10 and a sidewall of the basket 10 are formed with a strengthening structure 13.

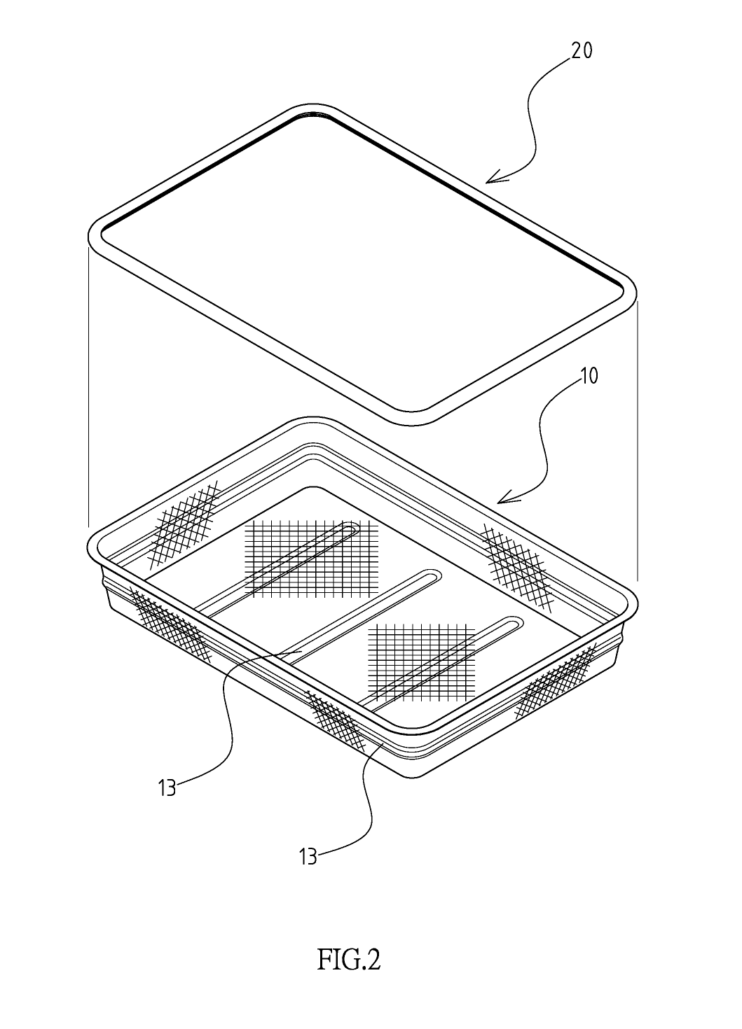

With reference to FIGS. 2-7, a metal basket in accordance with the present invention comprises an expanded mesh basket 10 and a frame 20 assembled to the expanded mesh basket 10, wherein the frame 20 is hollow annular structure and the expanded mesh basket 10 is formed with an open end and has a containing defined therein. The expanded mesh basket 10 has a flange 11 peripherally extending therefrom relative to the open end. A protective coating 11 is peripherally formed on the expanded mesh basket 10. The frame 20 surrounds the open end of the expanded mesh basket 10. The frame 20 includes an annular slit 21 inwardly defined therein and a protective coating 22 peripherally formed thereon. The protective coating 12 of the expanded mesh basket 10 has a color different from that of the protective coating 22 of the frame 20. The frame 20 is pressed and deformed such that the flange 11 is securely clamped between two opposite sides of the annular slit 21.

For improving the surface treatment effect and raising the peripheral brightness, the expanded mesh basket 10 and the frame 20 are pickled for removing the oxide and rust on the periphery of each of the expanded mesh basket 10 and the frame 20. With reference to FIG. 7, at least one through hole 23 is defined in the frame 20 for draining the pickle in the hollow frame 20 after being pickled. With reference to FIG. 7, for promoting the structure strength of the expanded mesh basket 10 of the present invention, at least one of a bottom of the basket 10 and a sidewall of the basket 10 formed a strengthening structure 13.

Although the invention has been explained in relation to its preferred embodiment, it is to be understood that many other possible modifications and variations can be made without departing from the spirit and scope of the invention as hereinafter claimed.

I claim:

1. A method for making a metal basket comprising the following steps:
preparing an expanded mesh basket and a hollow frame: the frame being a hollow annular structure and the expanded mesh basket formed with an open end and having a containing space defined therein, wherein the expanded mesh basket has a flange peripherally extending therefrom relative to the open end and an annular slit is inwardly defined in the frame;
surface treatment: the expanded mesh basket and the frame respectively processed by different surface treatment method and respectively peripherally formed with a protective coating, wherein the protective coating of the expanded mesh basket has a color different from that of the protective coating of the frame;
assembling the expanded mesh basket and the frame: the flange of the expanded mesh basket inserted into the frame through the annular slit; and
securing the expanded mesh basket with the frame: the frame being pressed and deformed by a mold such that the flange is securely clamped between two opposite sides of the annular slit.

2. The method as claimed in claim 1, wherein the surface treatment method of the expanded mesh basket and the frame is selected from the group consisted of baking finish, electroplating, anodic treatment, powder-paint coating, vapor deposition, sputtering and electrophoretic deposition.

3. The method as claimed in claim 1, wherein the expanded mesh basket and the frame are pickled for removing the oxide and rust on the periphery of each of the expanded mesh basket and the frame before the step of surface treatment.

4. The method as claimed in claim 2, wherein the expanded mesh basket and the frame are pickled for removing the oxide and rust on the periphery of each of the expanded mesh basket and the frame before the step of surface treatment.

5. The method as claimed in claim 3, wherein at least one of a bottom of the basket and a sidewall of the basket are formed with a strengthening structure.

6. The method as claimed in claim 4, wherein at least one of a bottom of the basket and a sidewall of the basket are formed with a strengthening structure.

7. A metal basket comprising:
an expanded mesh basket formed with an open end and having a containing space defined therein, wherein the expanded mesh basket has a flange peripherally extending therefrom relative to the open end and peripherally formed with a protective coating by surface treatment; and
a frame assembled to the expanded mesh basket and surrounding the open end of the expanded mesh basket, the frame being a hollow annular structure, peripherally formed with protective coating by surface treatment, and having an annular slit is inwardly defined in the frame, wherein the protective coating of the expanded mesh basket has a color different from that of the protective coating of the frame, and the flange is laterally inserted into the slit and securely clamped between two opposite sides of the slit after the frame being pressed and deformed.

8. The metal basket as claimed in claim 7, wherein the surface treatment method of the expanded mesh basket and the frame is selected from the group consisted of baking finish, electroplating, anodic treatment, powder-paint coating, vapor deposition, sputtering and electrophoretic deposition.

9. The metal basket as claimed in claim 7, wherein the frame has at least one through hole defined therein for draining pickle in the frame after being pickled.

10. The metal basket as claimed in claim 8, wherein the frame has at least one through hole defined therein for draining pickle in the frame after being pickled.

11. The metal basket as claimed in claim 9, wherein at least one of a bottom of the basket and a sidewall of the basket are formed with a strengthening structure.

12. The metal basket as claimed in claim 9, wherein at least one of a bottom of the basket and a sidewall of the basket are formed with a strengthening structure.
